(19) United States
(12) Patent Application Publication
(10) Pub. No.: US 2011/0142260 A1
(43) Pub. Date: Jun. 16, 2011

(54) METHOD AND APPARATUS FOR OUTPUTTING AUDIO SIGNAL IN PORTABLE TERMINAL

(75) Inventor: Young-Bae JANG, Suwon-si (KR)

(73) Assignee: SAMSUNG ELECTRONICS CO. LTD., Suwon-si (KR)

(21) Appl. No.: 12/962,827

(22) Filed: Dec. 8, 2010

(30) Foreign Application Priority Data
Dec. 15, 2009 (KR) 10-2009-0124481

(51) Int. Cl. H03G 3/00

(52) U.S. Cl. 381/104

(57) ABSTRACT

A method and an apparatus for outputting an audio signal in a portable terminal are provided. In the method, a touched coordinate of a screen is recognized. An output volume of each of a plurality of speakers is controlled according to the touched coordinate. An audio signal is output via the plurality of speakers whose output volume has been controlled.

### PRIORITY

This application claims the benefit under 35 U.S.C. §119(a) of a Korean patent application filed in the Korean Intellectual Property Office on Dec. 15, 2009, and assigned Serial No. 2009-0124481, the entire disclosure of which is hereby incorporated by reference.

### BACKGROUND OF THE INVENTION

1. Field of the Invention

The present invention relates to a method and an apparatus for outputting an audio signal in a portable terminal. More particularly, the present invention relates to a method and an apparatus for outputting an audio signal using a plurality of speakers in a portable terminal.

2. Description of the Related Art

Recently, with the advancement of computer and information telecommunication technology, portable terminals that meet a consumer's various tastes and requirements have been developed. More particularly, portable terminals having a touch screen are widely distributed. When a user touches a screen using his hand or a touch pen, the portable terminal having the touch screen recognizes a touched region of the screen using a touch sensor, and performs a function corresponding to the touched region. For example, the portable terminal selects data corresponding to the touched region or moves the screen according to a touch movement.

Compared to a receiving method through a keypad, a receiving method through the touch screen has an advantage of performing a desired function more swiftly by allowing a user to directly touch the screen. However, it has a disadvantage in that it is difficult to know whether a desired region is touched or whether the portable terminal accurately recognizes the touch. Therefore, to acknowledge the recognition of the touch screen input by the user, the portable terminal generates vibrations or outputs sounds set in advance when the user touches the screen. However, a method of generating vibrations or outputting sounds set in advance informs only whether the user's touch is recognized and cannot inform whether a desired region has been selected.

Therefore, a need exists for a method and an apparatus for representing a position at which a screen has been touched using a plurality of speakers in a portable terminal.

### SUMMARY OF THE INVENTION

An aspect of the present invention is to address at least the above-mentioned problems and/or disadvantages and to provide at least the advantages described below. Accordingly, an aspect of the present invention is to provide a method and an apparatus for outputting an audio signal using a plurality of speakers in a portable terminal.

Another aspect of the present invention is to provide a method and an apparatus for representing a position at which a screen has been touched using a plurality of speakers in a portable terminal.

Still another aspect of the present invention is to provide a method and an apparatus for controlling output volume of a plurality of speakers according to a position at which a screen has been touched in a portable terminal.

In accordance with an aspect of the present invention, a method for outputting an audio signal in a portable terminal is provided. The method includes recognizing a coordinate at which a screen is touched, controlling an output volume of each of a plurality of speakers according to the touched coordinate, and outputting audio signals via the plurality of speakers whose output volume has been controlled.

In accordance with another aspect of the present invention, an apparatus for outputting an audio signal in a portable terminal is provided. The apparatus includes a plurality of speakers for outputting an audio signal, an input unit for recognizing a coordinate at which a screen is touched, and a controller for controlling an output volume of each of the plurality of speakers according to the touched coordinate, and for controlling a function for outputting an audio signal via the plurality of speakers whose output volume has been controlled.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings in which:

FIG. 1 is a block diagram illustrating a portable terminal according to an exemplary embodiment of the present invention;

FIG. 2 is a flowchart illustrating an operation procedure of a portable terminal according to an exemplary embodiment of the present invention;

FIG. 3 is a view illustrating a portable terminal having a plurality of speakers according to an exemplary embodiment of the present invention;

FIG. 4 is a view illustrating a coordinate of a portable terminal according to an exemplary embodiment of the present invention; and

FIG. 5 is a view illustrating an output volume of a specific speaker depending on a touch position in a portable terminal according to an exemplary embodiment of the present invention.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. In addition, the terms and words are defined with consideration of functions in exemplary embodiments of the present invention and may change depending on the intentions or practices of a user and an operator. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

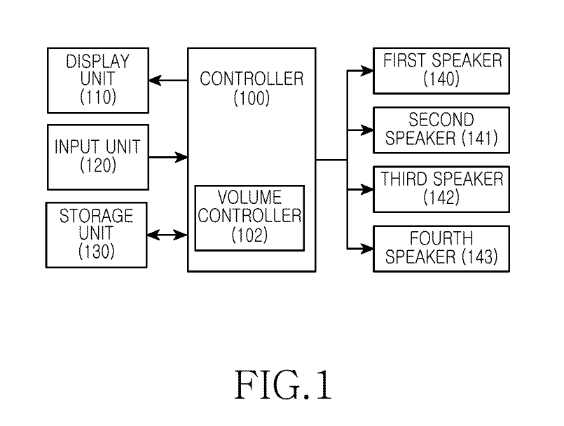

FIGS. 1 through 5, discussed below, and the various exemplary embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly state otherwise. A set is defined as a non-empty set including at least one element.

Exemplary embodiments of the present invention provide a method and an apparatus for controlling output volume of a plurality of speakers depending on a position at which a screen has been touched and outputting an audio signal set in advance in a portable terminal.

FIG. 1 is a block diagram illustrating a portable terminal according to an exemplary embodiment of the present invention.

Referring to FIG. 1, a portable terminal includes a controller 100, a display unit 110, an input unit 120, a storage unit 130, a first speaker 140, a second speaker 141, a third speaker 142, and a fourth speaker 143. The controller 100 includes a volume controller 102.

The controller 100 controls and processes an overall operation of the portable terminal. The controller controls and processes functions for determining output volume of the first to fourth speakers (140 to 143) depending on a position at which a screen has been touched, and controls output volume of the first to fourth speakers (140 to 143) to output predefined audio signals.

The volume controller 102 may determine the output volume of the first to fourth speakers (140 to 143) according to the coordinate of a position at which the screen of the portable terminal has been touched. The volume controller 102 determines the output volume of one of the first to fourth speakers 140 to 143 that is positioned at a region relatively close to a coordinate of the touched position as high, and determines the output volume that is relatively distant away from the touched coordinate as low. At this point, the volume controller 102 determines the output volume such that a summation of the output volume of the first to fourth speakers (140 to 143) is the same even when the coordinate of the touched position changes.

The display unit 110 displays various status information generated during an operation of the portable terminal (i.e., letters, still images, moving images, and the like).

The input unit 120 includes at least one function key and a touch sensor to provide data corresponding to a key pressed by a user to the controller 100, and recognizes a touchscreen input operation to provide a coordinate corresponding to the touched region to the controller 100.

The storage unit 130 stores various programs for an overall operation of the portable terminal, and stores an audio signal to be output at a point at which the screen is touched.

The first to fourth speakers (140 to 143) may be positioned at the corners of the portable terminal, respectively, or positioned at regions neighboring the corners of the screen to output audio signals with different volume level according to the coordinate at which the screen has been touched under control of the controller 100.

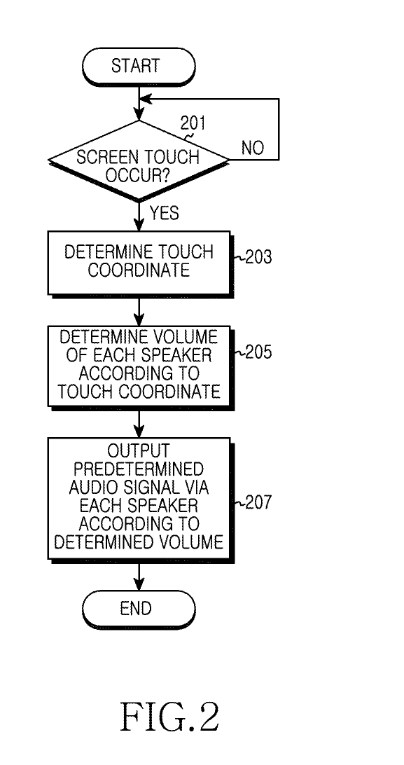

FIG. 2 is a flowchart illustrating an operation procedure of a portable terminal according to an exemplary embodiment of the present invention.

Referring to FIG. 2, a portable terminal determines whether a user has touched the screen in step 201. If it is determined in step 201 that the user has touched the screen, the portable terminal determines the touched coordinate in step 203.

In step 205, the portable terminal determines volume of respective plurality of speakers provided to the portable terminal according to the touched coordinate. At this point, the portable terminal determines the volume of one of the plurality of speakers that is positioned close to the touched coordinate as high, and determines the volume of a speaker that is positioned distant from the touched coordinate as low. In step 207, the portable terminal controls the volume of each speaker according to the determined volume and outputs a predefined audio signal. Thereafter, the portable terminal ends the algorithm according to an exemplary embodiment of the present invention.

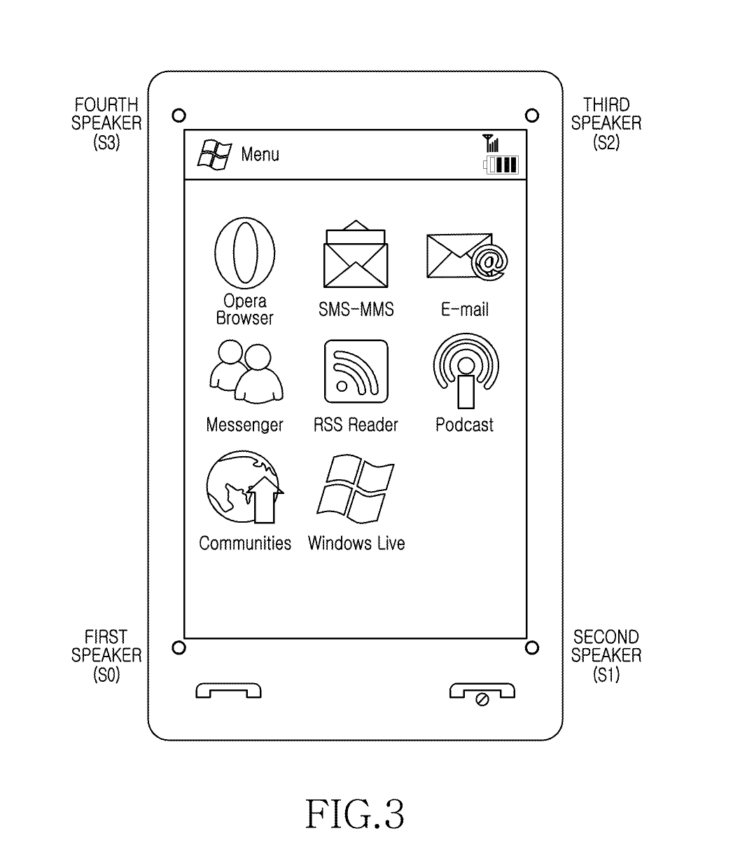

FIG. 3 is a view illustrating a portable terminal having a plurality of speakers according to an exemplary embodiment of the present invention

Referring to FIG. 3, four speakers positioned at each corner of a portable terminal or regions neighboring each corner of the screen of the portable terminal are illustrated. In this case, an output volume of the first speaker S0 of the first to fourth speakers S0, S1, S2, and S3 may be determined.

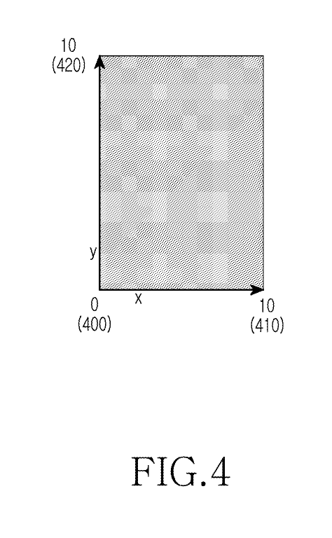

FIG. 4 is a view illustrating a coordinate of a portable terminal according to an exemplary embodiment of the present invention.

Referring to FIG. 4, a portable terminal sets a touched coordinate of the screen. Assuming that the screen is converted in terms of relative coordinates and the left lower end (400) is (0, 0), the right lower end (410) is (10, 0), the left upper end (420) is (0, 10), and the right upper end is (10, 10), when the coordinate of the touched position is (x, y), the volume controller 102 may set the output volume of each speaker using Equation (1).

S0=(10−x)*(10−y)

S1=x*(10−y)

S2=x*y

S3=(10−x)*y (1)

S0 denotes the output volume of the first speaker 140, S1 of the second speaker 141, S2 of the third speaker 142, and S3 of the fourth speaker 143. S0+S1+S2+S3 maintains a constant value as a maximum value of 100.

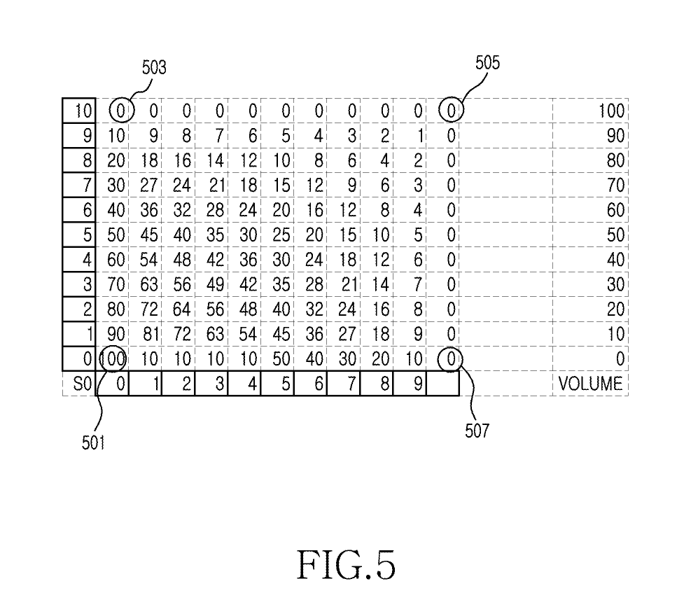

FIG. 5 is a view illustrating an output volume of a specific speaker depending on a touch position in a portable terminal according to an exemplary embodiment of the present invention.

Referring to FIG. 5, an output volume of the first speaker S0 of the first to fourth speakers S0, S1, S2, and S3 may be determined. That is, an output volume of the first speaker S0 is determined as high as a touched coordinate is close to the first speaker S0, and determined as low as the touched coordinate is distant away from the first speaker S0. For example, when the left lower end region 501 closest to the first speaker S0 is touched, the output volume of the first speaker S0 is determined as a maximum value of 100. When regions 503, 505, and 507 are positioned relatively distant from the first speaker S0 with respect to an x-axis and a y-axis are touched, the output volume of the first speaker S0 may be determined as a minimum value of 0.

As described above, though an exemplary embodiment of the present invention has been described using the case where a portable terminal has four speakers, the present invention is applicable to the case where a portable terminal has a plurality of speakers, more than two speakers. That is, in the case where a portable terminal has a plurality of speaker more than two, the portable terminal may determine an output volume of a speaker positioned relatively close to a touched coordinate as high, and determine an output volume of a speaker positioned distant away as low to output an audio signal.

An exemplary embodiment of the present invention controls output volume of a plurality of speakers depending on a position at which a screen has been touched and outputs a predefined audio signal, so that a user may recognize whether a desired region has been touched through an audio signal output when the screen is touched.

While the invention has been shown and described with reference to certain exemplary embodiments thereof, it will be understood by those skilled in the art that various changes in form and details may be made therein without departing from the spirit and scope of the invention as defined by the appended claims and their equivalents. Therefore, the scope of the present invention should not be limited to the above-described embodiments but should be determined by not only the appended claims but also the equivalents thereof.

What is claimed is:

1. A method for outputting an audio signal in a portable terminal, the method comprising:
recognizing a touched coordinate of a screen;
controlling an output volume of each of a plurality of speakers according to the touched coordinate; and
outputting audio signals via the plurality of speakers whose output volume has been controlled.

2. The method of claim 1, wherein the controlling of the output volume of each of the plurality of speakers comprises:
setting an output volume of a speaker positioned close to the touched coordinate to high; and
setting an output volume of a speaker positioned distant away from the touched coordinate to low.

3. The method of claim 1, wherein a summation of the output volume of the plurality of speakers is the same regardless of the touched coordinate.

4. The method of claim 1, wherein the plurality of speakers are positioned at corners of the portable terminal or at regions neighboring the corners of the screen.

5. The method of claim 1, wherein the plurality of speakers includes more than two speakers.

6. The method of claim 1, wherein when a left lower end region closest to a first speaker is touched, the output volume of the first speaker is determined as a maximum value, and when the other regions positioned relatively distant from the first speaker with respect to an x-axis and a y-axis are touched, the output volume of the first speaker may be determined as a minimum value.

7. An apparatus for outputting an audio signal in a portable terminal, the apparatus comprising:
a plurality of speakers for outputting an audio signal;
an input unit for recognizing a coordinate at which a screen is touched; and
a controller for controlling an output volume of each of the plurality of speakers according to the touched coordinate, and for controlling a function for outputting an audio signal via the plurality of speakers whose output volume has been controlled.

8. The apparatus of claim 7, wherein the controller sets an output volume of a speaker positioned close to the touched coordinate to high, and sets an output volume of a speaker positioned distant away from the touched coordinate to low.

9. The apparatus of claim 7, wherein the controller controls a summation of the output volume of the plurality of speakers to be the same regardless of the touched coordinate.

10. The apparatus of claim 7, wherein the plurality of speakers are positioned at corners of the portable terminal or at regions neighboring the corners of the screen.

11. The apparatus of claim 7, wherein the plurality of speakers includes more than two speakers.

12. The apparatus of claim 7, wherein when a left lower end region closest to a first speaker is touched, the output volume of the first speaker is determined as a maximum value, and when the other regions positioned relatively distant from the first speaker with respect to an x-axis and a y-axis are touched, the output volume of the first speaker may be determined as a minimum value.
